(19) United States
(12) Patent Application Publication
(10) Pub. No.: US 2024/0038795 A1
(43) Pub. Date: Feb. 1, 2024

(54) SEMICONDUCTOR PACKAGE AND IMAGE SENSOR PACKAGE

(71) Applicant: SAMSUNG ELECTRONICS CO., LTD., Suwon-si (KR)

(72) Inventor: Sang-Uk KIM, Suwon-si (KR)

(73) Assignee: SAMSUNG ELECTRONICS CO., LTD., Suwon-si (KR)

(21) Appl. No.: 18/196,276

(22) Filed: May 11, 2023

(30) Foreign Application Priority Data
Jul. 27, 2022 (KR) 10-2022-0093202

(51) Int. Cl. H01L 27/146; H01L 23/00

(52) U.S. Cl. CPC H01L 27/14618; H01L 24/29; H01L 24/32; H01L 27/14634; H01L 27/14623; H01L 27/14685; H01L 24/33; H01L 2224/33181; H01L 2224/33505; H01L 2224/2919; H01L 2224/2929; H01L 2924/0665; H01L 24/45; H01L 2224/45144; H01L 24/48; H01L 2224/48091; H01L 2224/48108; H01L 2224/48228; H01L 24/49; H01L 2224/49171; H01L 2224/29011; H01L 2224/32054; H01L 2224/29016; H01L 2224/33051; H01L 2224/29018; H01L 2224/32225; H01L 24/73; H01L 2224/73215; H01L 2224/73265; H01L 24/16; H01L 2224/16227; H01L 2224/3201; H01L 2224/32057; H01L 24/83; H01L 2224/83874; H01L 2224/83191; H01L 2224/83192; H01L 24/92; H01L 2224/92247; H01L 2224/92165; H01L 27/14627

(57) ABSTRACT

A semiconductor package includes: a package substrate; a semiconductor chip disposed on the package substrate; a transparent substrate disposed on the semiconductor chip; and an adhesive layer that is disposed between the semiconductor chip and the transparent substrate. The adhesive layer is configured to block light. The transparent substrate includes: a first lower side that faces the semiconductor chip, a second lower side that faces the semiconductor chip and that is disposed above the first lower side, and a first inner side wall that connects the first lower side and the second lower side, and the adhesive layer is in contact with the second lower side and the first inner side wall.

### CROSS-REFERENCE TO RELATED APPLICATION

This application claims priority from Korean Patent Application No. 10-2022-0093202 filed on Jul. 27, 2022 in the Korean Intellectual Property Office, the disclosure of which is herein incorporated by reference.

### BACKGROUND

### 1. Field

The present disclosure relates to a semiconductor package and an image sensor package.

### 2. Description of the Related Art

An image sensor is one of semiconductor elements that convert optical information into electrical signals. Such an image sensor may include a Charge-Coupled Device (CCD) image sensor and a Complementary Metal-Oxide Semiconductor (CMOS) image sensor.

The image sensor may be configured in the form of a package. At this time, the package protects the image sensor, and may also have a structure that allows light to enter a photo-receiving surface or a sensing area of the image sensor.

### SUMMARY

Provided are a semiconductor package having improved product reliability and an image sensor package having improved product reliability.

According to an aspect of the disclosure, a semiconductor package includes: a package substrate; a semiconductor chip disposed on the package substrate; a transparent substrate disposed on the semiconductor chip; and an adhesive layer that is disposed between the semiconductor chip and the transparent substrate. The adhesive layer is configured to block light. The transparent substrate includes: a first lower side that faces the semiconductor chip, a second lower side that faces the semiconductor chip and that is disposed above the first lower side, and a first inner side wall that connects the first lower side and the second lower side, and the adhesive layer is in contact with the second lower side and the first inner side wall.

According to another aspect of the disclosure, an image sensor package includes: a package substrate; an image sensor chip disposed on the package substrate, the image sensor chip includes a plurality of microlenses; a transparent substrate disposed on the image sensor chip; and an adhesive layer disposed between the image sensor chip and the transparent substrate, the adhesive layer configured to block light. The transparent substrate includes a protrusion protruding toward the image sensor chip in a central region of the transparent substrate that overlaps the plurality of microlenses. The adhesive layer is in contact with an upper side of the image sensor chip, and the adhesive layer is in contact with a side surface of the protrusion to surround the protrusion.

According to another aspect of the disclosure, an image sensor package includes: a package substrate; an image sensor chip disposed on the package substrate, the image sensor includes a plurality of microlenses; a transparent substrate disposed on the image sensor chip. The transparent substrate includes: a first portion having a first width, and a second portion disposed on the first portion and the second portion having a second width greater than the first width; and an adhesive layer that extents along an edge of the image sensor chip below the transparent substrate. The adhesive layer is configured to block light. The adhesive layer is in contact with an upper side of the image sensor chip, a side wall of the first portion, and a lower side of the second portion.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout diagram for illustrating a semiconductor package according to some embodiments;

FIG. 2 is a schematic cross-sectional view taken along line A-A of FIG. 1;

FIG. 3 is an enlarged view for illustrating a region P of FIG. 2;

FIG. 4 is an enlarged view for illustrating a region R of FIG. 2;

FIG. 5 is a schematic cross-sectional view for illustrating a semiconductor package according to some other embodiments;

FIGS. 6 and 7 are enlarged views for illustrating a region Q of FIG. 5;

FIG. 8 is a schematic cross-sectional view for illustrating a semiconductor package according to some other embodiments;

FIGS. 9 and 10 are schematic cross-sectional views for illustrating a semiconductor package according to some other embodiments;

FIG. 11 is a schematic layout diagram for illustrating a semiconductor package according to some embodiments;

FIG. 12 is a schematic cross-sectional view taken along B-B of FIG. 11;

FIGS. 13 and 14 are schematic cross-sectional views for illustrating a semiconductor package according to some embodiments; and

FIGS. 15 to 22 are intermediate stage diagrams for illustrating a method of fabricating the semiconductor package according to some embodiments.

### DETAILED DESCRIPTION OF THE EMBODIMENTS

Hereinafter, embodiments according to the technical concept of the present disclosure will be described with reference to the accompanying drawings.

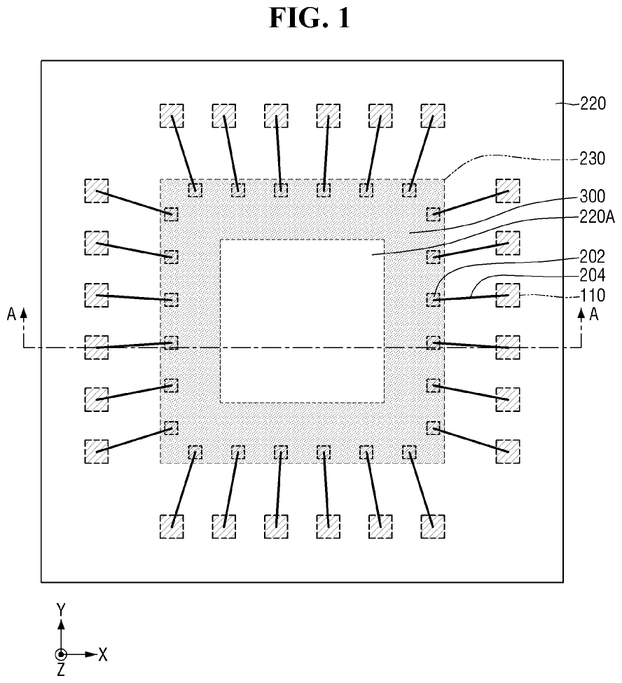

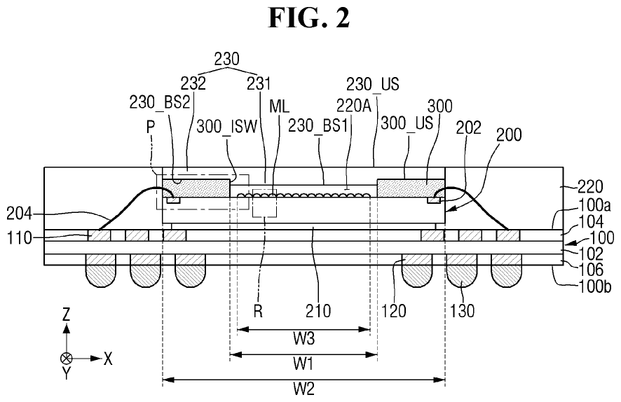

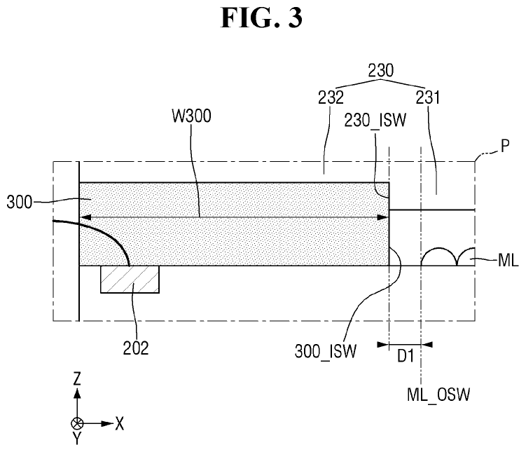

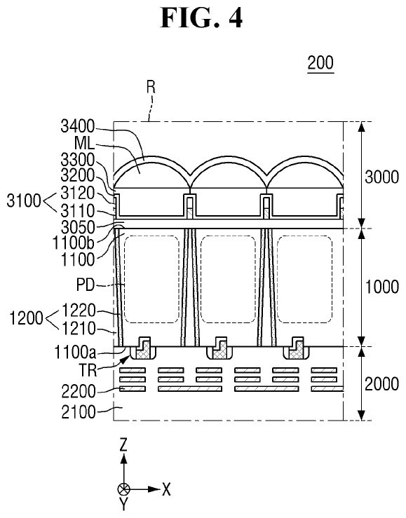

FIG. 1 is a schematic layout diagram for illustrating a semiconductor package according to some embodiments. FIG. 2 is a schematic cross-sectional view taken along line A-A of FIG. 1. FIG. 3 is an enlarged view for illustrating a region P of FIG. 2. FIG. 4 is an enlarged view for illustrating a region R of FIG. 2.

Referring to FIGS. 1 to 4, the semiconductor package according to some embodiments includes a first package substrate 100, a first connection terminal 130, a first semiconductor chip 200, a transparent substrate 230, an adhesive layer 300, and a molding film 220.

The first package substrate 100 may be a substrate for a semiconductor package. As an example, the first package substrate 100 may be a Printed Circuit Board (PCB). Alternatively, the first package substrate 100 may be a ceramic substrate, a substrate for a Wafer Level Package (WLP) or a substrate for a Package Level Package (PLP).

The first package substrate 100 may include a first side 100a and a second side 100b that are opposite to each other. In some embodiments, the first package substrate 100 may include a first wiring layer 102, a first substrate pad 110, and a second substrate pad 120.

The first substrate pad 110 may be disposed on the upper side of the first wiring layer 102. The first substrate pad 110 may be exposed from the upper side of the first package substrate 100. For example, the first substrate pad 110 may be exposed by a first protective layer 104 that covers the upper side of the first wiring layer 102. The first protective layer 104 may be, but not limited to, a solder resist layer.

The second substrate pad 120 may be disposed on a lower side of the first wiring layer 102. The second substrate pad 120 may be exposed from the lower side of the first package substrate 100. For example, the second substrate pad 120 may be exposed by a second protective layer 106 that covers the lower side of the first wiring layer 102. The second protective layer 106 may be, but not limited to, a solder resist layer.

The first wiring layer 102 may include insulating films, such as a plastic material or a ceramic material, and conductive vias and conductive wirings disposed inside the insulating films. The first substrate pad 110 and the second substrate pad 120 may be electrically connected by the conductive vias and the conductive wirings of the first wiring layer 102.

The first wiring layer 102 may include, for example, but not limited to, at least one of phenolic resin, epoxy resin, and polyimide. As an example, the first wiring layer 102 may include at least one of Flame Retardant 4 (FR4), tetrafunctional epoxy, polyphenylene ether, epoxy/polyphenylene oxide, BT (bismaleimide triazine), thermount, cyanate ester, polyimide, and liquid crystal polymer.

The first substrate pad 110 and the second substrate pad 120 may each include, but not limited to, at least one of copper (Cu), beryllium copper, nickel (Ni) and stainless steel.

In some embodiments, the first package substrate 100 may include a Copper Clad Laminate (CCL). For example, the first package substrate 100 may have a structure in which a copper foil is stacked on one side or both sides of thermoset prepreg (e.g., prepreg of a C-stage). As an example, the first substrate pad 110 and the second substrate pad 120 may be portions exposed by the first protective layer 104 and the second protective layer 106 of the circuit wirings patterned after applying a copper foil to the surface of the first wiring layer 102.

The first connection terminals 130 may be disposed on the second side 100b of the first package substrate 100. The first connection terminal 130 may be electrically connected to the first package substrate 100. For example, the first connection terminal 130 may be attached to the second substrate pad 120 of the first package substrate 100. The first connection terminal 130 may be, for example, solder balls, bumps, or the like. That is, the first package substrate 100 may be a Ball Grid Array (BGA) substrate. The first connection terminal 130 may include, but not limited to, metal such as tin (Sn). The first connection terminal 130 may electrically connect the semiconductor package according to some embodiments and an external electronic device.

The first semiconductor chip 200 may be disposed on the first side 100a of the first package substrate 100. For example, an attachment film 210 may be formed on the first side 100a of the first package substrate 100. The attachment film 210 may include, for example, but not limited to, liquid epoxy, adhesive tape or conductive media. The first semiconductor chip 200 is attached onto the attachment film 210 and fixed onto the first side 100a of the first package substrate 100.

The first semiconductor chip 200 may be electrically connected to the first package substrate 100. In some embodiments, a bonding wire 204 that connects the first package substrate 100 and the first semiconductor chip 200 may be formed. As an example, the first semiconductor chip 200 may include a first chip pad 202 exposed from the upper side of the first semiconductor chip 200. The bonding wire 204 may connect the first substrate pad 110 of the first package substrate 100 and the first chip pad 202 of the first semiconductor chip 200. The bonding wire 204 may include, but not limited to, metal such as gold (Au).

In one example, the first semiconductor chip 200 is electrically connected to the first package substrate 100 by the bonding wire 204. In another example, the first semiconductor chip 200 may be electrically connected to the first package substrate 100 by a bonding tape, or may be electrically connected to the first package substrate 100 by a flip-chip bonding manner.

In some embodiments, the first semiconductor chip 200 may be an image sensor chip. For example, as shown in FIG. 4, the first semiconductor chip 200 may include a photoelectric conversion unit 1000, a wiring structure unit 2000, and a light transmission unit 3000.

The photoelectric conversion unit 1000 may include a semiconductor substrate 1100, a pixel separation pattern 1200, and a photoelectric conversion layer PD.

The semiconductor substrate 1100 may be, for example, bulk silicon or Silicon-On-Insulator (SOI). The semiconductor substrate 1100 may be a silicon substrate, or may include other materials, for example, silicon germanium, indium antimonide, lead telluride, indium arsenide, indium phosphide, gallium arsenide or gallium antimonide. Alternatively, the semiconductor substrate 1100 may have an epitaxial layer formed on a base substrate.

The semiconductor substrate 1100 may include a front side 1100a and a back side 1100b that are opposite to each other. In some embodiments, the back side 1100b of the semiconductor substrate 1100 may be a photo-receiving surface on which light is incident. That is, the first semiconductor chip 200 may be a back illuminated (BSI) image sensor chip.

In some embodiments, transistors TR may be disposed on the front side 1100a of the semiconductor substrate 1100. The transistors TR may include, for example, at least some of various transistors (e.g., a transfer transistor, a reset transistor, a source follower transistor, a selection transistor, etc.) that form a unit pixel of an image sensor.

The pixel separation pattern 1200 may define a plurality of unit pixels inside the semiconductor substrate 1100. The unit pixels may be arranged two-dimensionally (for example, in the form of a matrix) from a planar viewpoint. For example, the pixel separation pattern 1200 may be formed in a grid pattern from the planar viewpoint to separate the unit pixels from each other. For example, the pixel separation pattern 1200 may be formed by filling an insulating material inside a deep trench formed by patterning the semiconductor substrate 1100.

In some embodiments, the pixel separation pattern 1200 may include an insulating spacer film 1220 and a conductive filling pattern 1210. The insulating spacer film 1220 may extend conformally along the side surfaces of the trench inside the semiconductor substrate 1100. The conductive filling pattern 1210 may be formed on the insulating spacer film 1220 and fill at least a part of the trench inside the semiconductor substrate 1100.

Each unit pixel may include a photoelectric conversion layer PD. A photoelectric conversion layer PD may be formed in the semiconductor substrate 1100. The photoelectric conversion layer PD may generate electric charges in proportion to an amount of light incident from the outside. The photoelectric conversion layer PD may be formed by doping impurities in the semiconductor substrate 1100. For example, the photoelectric conversion layer PD may be formed by ion-implanting an n-type impurity into the p-type semiconductor substrate 1100.

The wiring structure unit 2000 may be disposed on the front side 1100a of the semiconductor substrate 1100. The wiring structure unit 2000 may cover the transistors TR. The wiring structure unit 2000 may include readout circuits and sampling circuits electrically connected to the photoelectric conversion layer PD. As an example, the wiring structure unit 2000 may include an inter-wiring insulating film 2100 that covers the front side 1100a of the semiconductor substrate 1100, and wirings 2200 inside the inter-wiring insulating film 2100.

The light transmission unit 3000 may be disposed on the back side 1100b of the semiconductor substrate 1100. The light transmission unit 3000 may include a plurality of microlenses ML. The microlenses ML may be arranged to correspond to each unit pixel. For example, the microlenses ML may be arranged two-dimensionally (for example, in the form of a matrix) from the planar viewpoint.

The microlenses ML have a convex shape, and may have a predetermined radius of curvature. Therefore, the microlenses ML may condense the light incident on the photoelectric conversion layer PD. The microlenses ML may include, for example, but not limited to, a light-transmitting resin.

In some embodiments, the light transmission unit 3000 may further include a surface insulating film 3050 and a color filter 3300. The surface insulating film 3050 may be stacked on the back side 1100b of the semiconductor substrate 1100. The color filter 3300 may be disposed on the surface insulating film 3050. The color filter 3300 may be arranged to correspond to each unit pixel UP.

In some embodiments, a grid pattern 3100 may be formed between the color filters 3300. The grid pattern 3100 may be formed on the surface insulating film 3050. In some embodiments, the grid pattern 3100 may include a metal pattern 3110 and a low refractive index pattern 3120. For example, the metal pattern 3110 and the low refractive index pattern 3120 may be sequentially stacked on the surface insulating film 3050.

In some embodiments, a first liner 3200 may be further formed on the surface insulating film 3050 and the grid pattern 3100. The first liner 3200 may include, for example, but not limited to, aluminum oxide.

In some embodiments, a second liner 3400 may be further formed on the microlenses ML. The second liner 3400 may extend along the surface of the microlens 280. The second liner 3400 may include, for example, but not limited to, inorganic oxide film (e.g., silicon oxide, titanium oxide, zirconium oxide, hafnium oxide, and combinations thereof).

The transparent substrate 230 may be disposed on the upper side of the first semiconductor chip 200. The transparent substrate 230 may be opposite to the first semiconductor chip 200. The transparent substrate 230 may be opposite to the microlenses ML of the first semiconductor chip 200. Light provided to the semiconductor package may penetrate the transparent substrate 230 to reach the first semiconductor chip 200. The transparent substrate 230 may be, for example, but not limited to, a glass substrate or a plastic substrate.

The upper side of the transparent substrate 230 may be flat. The upper side of the transparent substrate 230 may include no step. The transparent substrate 230 may receive light through the front side. The upper side of the transparent substrate 230 may receive light through an entire area.

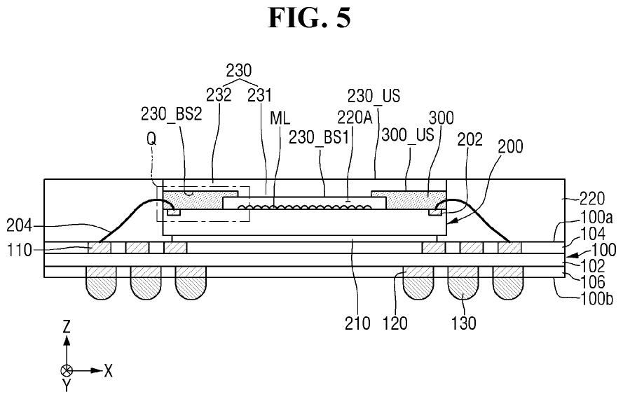

As illustrated in FIG. 5, the lower side of the transparent substrate 230 may have different heights. Specifically, the transparent substrate 230 may have a first lower side 230_BS1 and a second lower side 230_BS2. The first lower side 230_BS1 may be disposed in a central region of the transparent substrate 230. The first lower side 230_BS1 may be disposed on a center portion of the first semiconductor chip 200. The first lower side 230_BS1 may overlap the microlenses ML of the first semiconductor chip 200. The second lower side 230_BS2 may be disposed on an edge portion of the first semiconductor chip 200. The second lower side 230_BS2 may not overlap the microlenses ML of the first semiconductor chip 200.

The second lower side 230_BS2 may be disposed outside the first lower side 230_BS1. The second lower side 230_BS2 may surround the first lower side 230_BS1. The second lower side 230_BS2 may be disposed to be higher than the first lower side 230_BS1. That is, the second lower side 230_BS2 may be disposed above the first lower side 230_BS1.

As the second lower side 230_BS2 is disposed above the first lower side 230_BS1, an inner side wall 230 ISW of the transparent substrate 230 may be disposed between the first lower side 230_BS1 and the second lower side 230_BS2. That is, since the first lower side 230_BS1 and the second lower side 230_BS2 are disposed with a step, the inner side wall 230_ISW of the transparent substrate 230 may be disposed. The inner side wall 230_ISW may connect the first lower side 230_BS1 and the second lower side 230_BS2. The transparent substrate 230 may include a first region 231 and a second region 232.

As illustrated in FIG. 5, the first region 231 may be disposed below the second region 232. The first region 231 may overlap a part of the second region 232. The first region 231 may protrude from the second region 232 toward the first semiconductor chip 200. The first region 231 may refer to a protrusion of the transparent substrate 230. The first region 231 may have a first width W1. The first width W1 is smaller than the second width W2.

The second region 232 and the first region 231 may overlap. The second region 232 may be disposed above the first region 231. The second region 232 may cover the first region 231. The second region 232 may have a second width W2. The second width W2 is greater than the first width W1.

The first lower side 230_BS1 may refer to the lower side of the first region 231. The second lower side 230_BS2 may refer to the lower side of a part of the second region 232 that does not overlap the first region 231. The first region 231 protrudes from the second region 232, and the first lower side 230_BS1 may be disposed to be lower than the second lower side 230_BS2.

The adhesive layer 300 may be disposed between the first semiconductor chip 200 and the transparent substrate 230. The adhesive layer 300 may fix the transparent substrate 230 onto the upper side of the first semiconductor chip 200. The adhesive layer 300 may include, for example, but not limited to, an epoxy resin composition containing a filler.

The adhesive layer 300 may block light. The adhesive layer 300 may have a lower light transmissivity than the transparent substrate 230. The adhesive layer 300 may have a higher light absorptivity than the transparent substrate 230. The adhesive layer 300 may be opaque. For example, the adhesive layer 300 may exhibit a dark color.

The adhesive layer 300 may be disposed on the upper side of the first semiconductor chip 200. The adhesive layer 300 may contact with the upper side of the first semiconductor chip 200. The adhesive layer 300 may cover the first chip pad 202. In one embodiment, the adhesive layer 300 may cover a part of the bonding wire 204. In another embodiment, the adhesive layer 300 may expose the first chip pad 202. In such a case, the adhesive layer 300 may not cover the bonding wire 204.

The adhesive layer 300 may be disposed below the transparent substrate 230. The adhesive layer 300 may be disposed below the second region 232 that does not overlap the first region 231 of the transparent substrate 230. The adhesive layer 300 may be disposed below the second lower side 230_BS2 of the transparent substrate 230. The adhesive layer 300 may contact with the second lower side 230_BS2 of the transparent substrate 230. An upper side 300_US of the adhesive layer 300 may contact with the second lower side 230_BS2 of the transparent substrate 230. The adhesive layer 300 may contact with the inner side wall 230_ISW of the transparent substrate 230.

The adhesive layer 300 may have a constant width. The adhesive layer 300 may have a constant width W300 in a first direction X. The width of the lower side of the adhesive layer 300 that contacts with the first semiconductor chip 200 may be the same the width of the upper side of the adhesive layer 300 that contacts with the transparent substrate 230.

The adhesive layer 300 may include an inner side wall 300 ISW. The inner side wall 300_ISW of the adhesive layer 300 may contact with the inner side wall 230_ISW of the transparent substrate 230. The inner side wall 300 ISW of the adhesive layer 300 may be disposed in the same plane as the inner side wall 230_ISW of the transparent substrate 230. The inner side wall 300_ISW of the adhesive layer 300 that contacts with the inner side wall 230_ISW of the transparent substrate 230 may be flat. For example, referring to FIG. 3, the inner side wall 300_ISW of the adhesive layer 300 may extend with no protruding portion.

The adhesive layer 300 may not be disposed below the first lower side 230_BS1 of the transparent substrate 230. The adhesive layer 300 may not overlap the first lower side 230_BS1 of the transparent substrate 230.

In some embodiments, the adhesive layer 300 may define a gap 220A between the first semiconductor chip 200 and the transparent substrate 230. For example, the adhesive layer 300 may extend along the edge of the first semiconductor chip 200 to form a closed ring from a planar viewpoint. Accordingly, the transparent substrate 230 may be spaced apart from the first semiconductor chip 200 by the gap 220A. A plurality of microlenses ML of the first semiconductor chip 200 may be disposed inside the gap 220A.

The adhesive layer 300 may surround the plurality of microlenses ML from the planar viewpoint. The adhesive layer 300 may not overlap the plurality of microlenses ML. The adhesive layer 300 may be disposed below the second region 232 of the transparent substrate 230 that does not overlap the plurality of microlenses ML.

The plurality of microlenses ML may be disposed below the first lower side 230_BS1 of the transparent substrate 230. The plurality of microlenses ML may overlap the first lower side 230_BS1 of the transparent substrate 230. The plurality of microlenses ML may be disposed at a third width W3. That is, the region in which the plurality of microlenses ML are aligned may have the third width W3.

The third width W3 may be equal to or smaller than the first width W1. The first lower side 230_BS1 may overlap the region in which the plurality of microlenses ML are aligned. The size of the first lower side 230_BS1 may be greater than or equal to the size of the region in which the plurality of microlenses ML are aligned. The first width W1 of the first lower side 230_BS1 may be greater than or equal to the third width W3 of the region in which the plurality of microlenses ML are aligned.

The plurality of microlenses ML may be spaced apart from the second lower side 230_BS2 of the transparent substrate 230. For example, referring to FIG. 3, the plurality of microlenses ML may be spaced apart from the second lower side 230_BS2 of the transparent substrate 230 by a first distance D1.

Specifically, the inner side wall 230_ISW that connects the second lower side 230_BS2 and the first lower side 230_BS1 of the transparent substrate 230 may be spaced apart from the microlens ML disposed in the outermost part among the plurality of microlenses ML by the first distance D1. The inner side wall 230_ISW of the transparent substrate 230 may not overlap the microlenses ML.

The distance between the inner side wall 230_ISW of the transparent substrate 230 and the outer side wall ML_OSW of the microlens ML disposed at the outermost part may be the first distance D1. That is, the first distance D1 may refer to a distance by which the first lower side 230_BS1 of the transparent substrate 230 extends beyond the region in which the plurality of microlenses ML is aligned on the cross-sectional view. At this time, the first distance D1 may be 50 μm or less.

The adhesive layer 300 may be disposed below the transparent substrate 230 having the first lower side 230_BS1 and the second lower side 230_BS2 having different heights, thereby blocking the light incident from outside. For example, light incident from the side of the transparent substrate 230 may be blocked, other than light incident from the front of the transparent substrate 230.

Since the adhesive layer 300 is disposed below the transparent substrate 230 having the step and the adhesive layer 300 fills the step, incident external light may be blocked in a wider range of angles.

In one example, the flat side surface of the adhesive layer 300 is shown. In another example, the side surface of the adhesive layer 300 may be concave or convex, depending on the constituent material of the adhesive layer 300, the method of forming the adhesive layer 300, and the like.

A molding film 220 may be disposed on the first package substrate 100. The molding film 220 may surround the first semiconductor chip 200, the transparent substrate 230 and the adhesive layer 300. The molding film 220 may be disposed on the side surfaces of the first semiconductor chip 200, the transparent substrate 230 and the adhesive layer 300. The molding film 220 may cover the bonding wire 204.

The molding film 220 may include an insulating material. For example, the molding film 220 may include thermosetting resins such as epoxy resins, thermoplastic resins such as polyimides, or resins (e.g., prepreg, ABF (Ajinomoto Build-up Film), FR-4, and BT (Bismaleimide Triazine)), in which these resins are mixed with inorganic fillers or impregnated into core materials such as glass fibers (glass fiber, glass cloth, and glass fabric) together with the inorganic fillers. Alternatively, the molding film 220 may include a photoimageable dielectric (PID).

In FIGS. 1 to 3, the width (or size) of the transparent substrate 230 is shown as being the same as the width (or size) of the first semiconductor chip 200. In another example, the width (or size) of the transparent substrate 230 may be smaller or greater than the width (or size) of the first semiconductor chip 200.

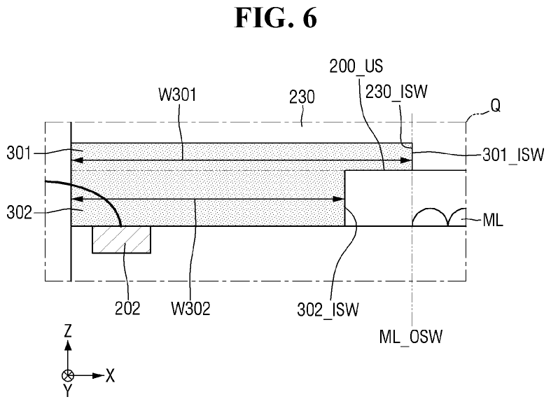

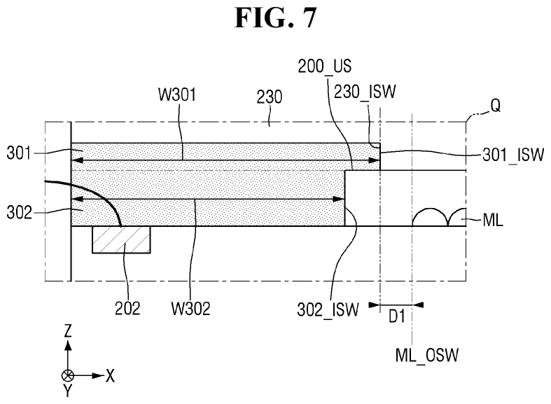

FIG. 5 is a schematic cross-sectional view for illustrating a semiconductor package according to some other embodiments. FIGS. 6 and 7 are enlarged views for illustrating a region Q of FIG. 5. The following disclosure will be mainly provided on points that are different from those described with reference to FIGS. 1 to 4.

Referring to FIGS. 5 to 7, the adhesive layer 300 may include a first portion 301 and a second portion 302 having different widths. The inner side walls of the adhesive layer 300 may not be flat.

The first portion 301 may refer to a portion that contacts with the second lower side 230_BS2 and the inner side wall 230_ISW of the transparent substrate 230. That is, the first portion 301 may refer to a portion that fills the step of the transparent substrate 230. The second portion 302 may refer to a portion that contacts with the upper side of the first semiconductor chip 200.

The first portion 301 may be disposed above the second portion 302. The first portion 301 may extend further toward the center portion of the first semiconductor chip 200 beyond the second portion 302. The first portion 301 may protrude toward the inner side wall 230_ISW of the transparent substrate 230.

The adhesive layer 300 may not have a uniform width. Specifically, the first portion 301 may have a first portion width W301. The second portion 302 may have a second portion width W302. The first portion width W301 may be greater than the second portion width W302.

The inner side wall 302_ISW of the second portion 302 may be disposed outside the inner side wall 230_ISW of the transparent substrate 230. The inner side wall 301_ISW of the first portion 301 may be disposed on the same plane as the inner side wall 230_ISW of the transparent substrate 230.

A part of the first portion 301 that protrudes inward from the second portion 302 and the inner side wall 302_ISW of the second portion 302 may define a gap 220A between the first semiconductor chip 200 and the transparent substrate 230.

Even if the first portion 301 protrudes beyond the second portion 302, the first portion 301 may not overlap the plurality of microlenses ML. That is, the inner side wall 301_ISW of the first portion 301 may be disposed on the same plane as the outer side wall ML_OSW of the outermost microlens ML or may be disposed outside.

For example, referring to FIG. 6, the inner side wall 301_ISW of the first portion 301 may be disposed on the same plane as the outer side wall ML_OSW of the outermost microlens ML.

As another example, referring to FIG. 7, the inner side wall 301_ISW of the first portion 301 and the outer side wall ML_OSW of the outermost microlens ML may be spaced apart by the first distance D1. At this time, the first distance D1 may be 50 μm or less.

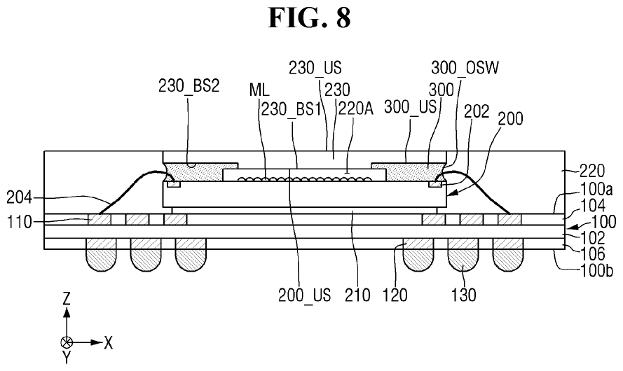

FIG. 8 is a schematic cross-sectional view for illustrating a semiconductor package according to some other embodiments. The following disclosure will be mainly provided on points that are different from those described with reference to FIGS. 1 to 7.

Referring to FIG. 8, the adhesive layer 300 may have a concave outer side wall 300_OSW. The outer side wall 300_OSW of the adhesive layer 300 may be recessed inward. The outer side wall 300_OSW of the adhesive layer 300 may be concavely bent toward the center portion of the first semiconductor chip 200.

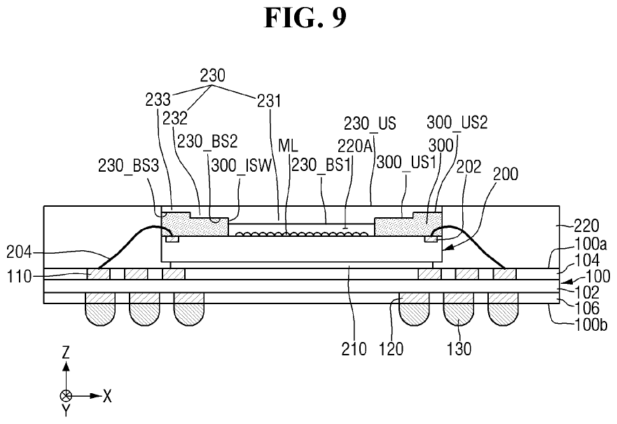

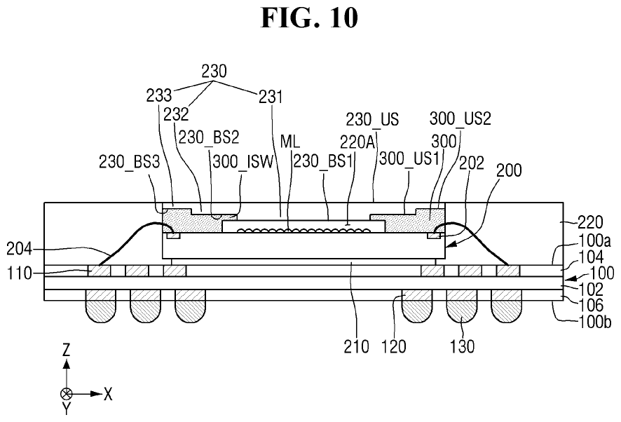

FIGS. 9 and 10 are schematic cross-sectional views for illustrating a semiconductor package according to some other embodiments. The following disclosure will be mainly provided on points that are different from those described with reference to FIGS. 1 to 8.

Referring to FIGS. 9 and 10, the transparent substrate 230 may include a first region 231, a second region 232 and a third region 233. The third region 233 may be disposed on the second region 232. The second region 232 may protrude from the third region 233.

The transparent substrate 230 may have a first lower side 230_BS1, a second lower side 230_BS2, and a third lower side 230_BS3. The third lower side 230_BS3 may be disposed to be higher than the first lower side 230_BS1 and the second lower side 230_BS2.

The third lower side 230_BS3 may be disposed above the second lower side 230_BS2. An inner side wall of the transparent substrate 230 may be disposed between the second lower side 230_BS2 and the third lower side 230_BS3.

The third lower side 230_BS3 may be disposed on an edge portion of the first semiconductor chip 200. The third lower side 230_BS3 may not overlap the microlenses ML of the first semiconductor chip 200. The third lower side 230_BS3 may be disposed outside the second lower side 230_BS2. The third lower side 230_BS3 may surround the second lower side 230_BS2.

An upper side of the adhesive layer 300 may have a step. Specifically, the adhesive layer 300 may have a first upper side 300_US1 that contacts with the second lower side 230_BS2 of the transparent substrate 230. The adhesive layer 300 may have a second upper side 300_US2 that contacts with the third lower side 230_BS3 of the transparent substrate 230. The second upper side 300_US2 may be disposed to be higher than the first upper side 300_US1.

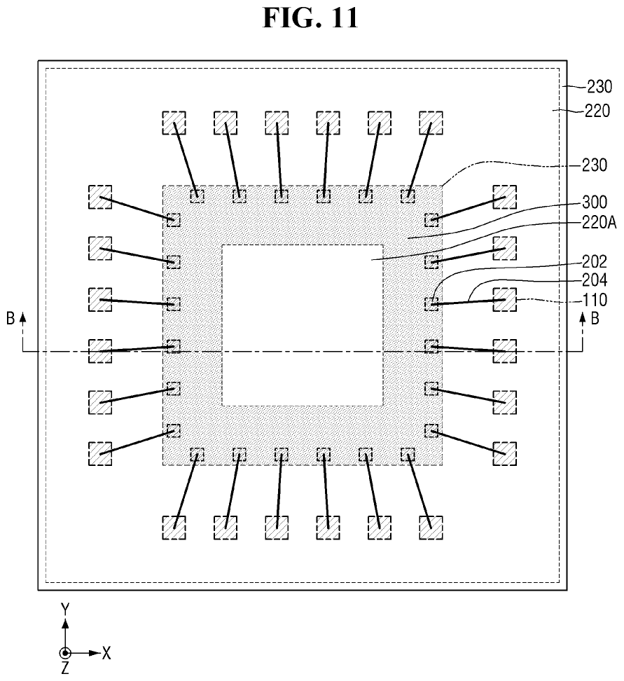

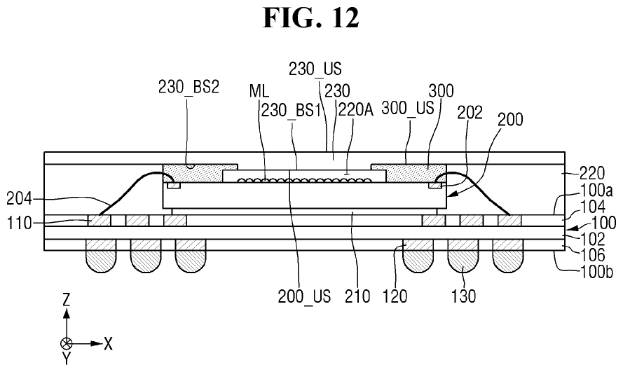

FIG. 11 is a schematic layout diagram for illustrating a semiconductor package according to some embodiments. FIG. 12 is a schematic cross-sectional view taken along B-B of FIG. 11. The following disclosure will be mainly provided on points that are different from those described with reference to FIGS. 1 to 10.

Referring to FIGS. 11 and 12, in the semiconductor package according to some embodiments, the transparent substrate 230 may cover the upper side of the molding film 220. For example, the transparent substrate 230 may extend along the upper side of the adhesive layer 300 and the upper side of the molding film 220. The second lower side 230_BS2 of the transparent substrate 230 may cover the upper side of the molding film 220. The second lower side 230_BS2 of the transparent substrate 230 may further extend outward beyond the adhesive layer 300.

The transparent substrate 230 may cover the adhesive layer 300. The adhesive layer 300 may overlap a part of the second lower side 230_BS2 of the transparent substrate 230. The side surface of the transparent substrate 230 may be disposed on the same plane as the side surface of the first package substrate 100.

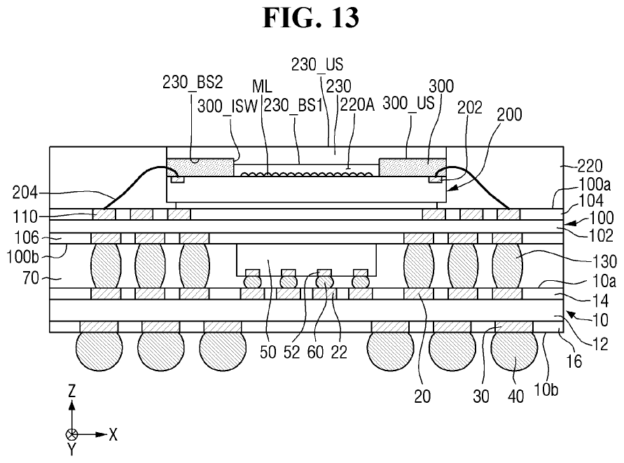

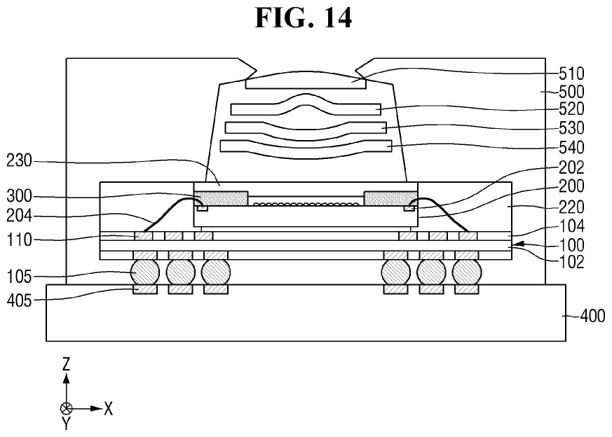

FIGS. 13 and 14 are schematic cross-sectional views for illustrating a semiconductor package according to some embodiments. The following disclosure will be mainly provided on points that are different from those described with reference to FIGS. 1 to 12.

Referring to FIG. 13, the semiconductor package according to some embodiments may further include a second package substrate 10, a second connection terminal a second semiconductor chip 50, and a third molding film 70.

The second package substrate 10 may be a substrate for a semiconductor package. As an example, the second package substrate 10 may be a Printed Circuit Board (PCB). Alternatively, the second package substrate 10 may be a ceramic substrate, or may be a substrate for a Wafer Level Package (WLP), or a substrate for a Package Level Package (PLP).

The second package substrate 10 may include a third side 10a and a fourth side that are opposite to each other. The third side 10a of the second package substrate 10 may be opposite to the second side 100b of the first package substrate 100. In some embodiments, the second package substrate 10 may include a second wiring layer 12, a third substrate pad 20, and a fourth substrate pad 30.

The third substrate pad 20 may be disposed on the upper side of the second wiring layer 12. The third substrate pad 20 may be exposed from the upper side of the second package substrate 10. For example, the third substrate pad 20 may be exposed by the third protective layer 14 that covers the upper side of the second wiring layer 12. The third protective layer 14 may be, but not limited to, a solder resist layer.

The fourth substrate pad 30 may be disposed on the lower side of the second wiring layer 12. The fourth substrate pad 30 may be exposed from the lower side of the second package substrate 10. For example, the fourth substrate pad 30 may be exposed by the fourth protective layer 16 that covers the lower side of the second wiring layer 12. The fourth protective layer 16 may be, but not limited to, a solder resist layer.

The second wiring layer 12 may include insulating films, such as a plastic material or a ceramic material, and conductive vias and conductive wirings disposed inside the insulating films. The third substrate pad 20 and the fourth substrate pad 30 may be electrically connected by the conductive vias and the conductive wirings of the second wiring layer 12.

The second connection terminal 40 may be disposed on the fourth side 10b of the second package substrate 10. The second connection terminal 40 may be electrically connected to the second package substrate 10. For example, the second connection terminal may be attached to the fourth substrate pad 30 of the second package substrate 10. The second connection terminal 40 may be, for example, solder balls, bumps, or the like. The second connection terminal 40 may electrically connect the semiconductor package according to some embodiments and an external electronic device.

In some embodiments, the first package substrate 100 and the second package substrate 10 may be electrically connected. For example, the first connection terminal 130 may connect the third substrate pad 20 of the second package substrate 10 and the second substrate pad 120 of the first package substrate 100.

The second semiconductor chip 50 may be disposed on the third side 10a of the second package substrate 10. The second semiconductor chip 50 may be electrically connected to the second package substrate 10. In some embodiments, a third connection terminal 60 that connects the second package substrate 10 and the second semiconductor chip 50 may be formed. As an example, the second semiconductor chip 50 may include a second chip pad 52 exposed from the lower side of the second semiconductor chip 50. The third connection terminal 60 may connect the third substrate pad 20 of the second package substrate 10 and the second chip pad 52 of the second semiconductor chip 50. That is, the second semiconductor chip 50 may be disposed on the second package substrate 10 by a flip chip bonding manner. The third connection terminal 60 may be, for example, but not limited to, a microbump.

In one example, the second semiconductor chip 50 is electrically connected to the second package substrate 10 by the flip-chip bonding manner. In another example, the second semiconductor chip 50 may be electrically connected to the second package substrate 10 by a bonding wire, a bonding tape, or the like.

In some embodiments, the second semiconductor chip 50 may include, but not limited to, at least one of a memory semiconductor chip, a digital signal process integrated circuit, an Application Specific Integrated Circuit (ASIC) and a driver.

A third molding film 70 may be formed on the third side 10a of the second package substrate 10. The third molding film 70 may fill a space between the first package substrate 100 and the second package substrate 10. For example, the third molding film 70 may surround the side surfaces of the second semiconductor chip 50. The first connection terminal 130 may penetrate the third molding film 70 to connect the first package substrate 100 and the second package substrate 10. The third connection terminal 60 may penetrate the third molding film 70 to connect the second package substrate 10 and the second semiconductor chip 50. For example, the third molding film 70 may include an insulating polymer material such as an Epoxy Molding Compound (EMC).

Referring to FIG. 14, an image sensor package according to some embodiments may further include a housing 500 and a third package substrate 400.

The housing 500 may wrap the first semiconductor chip 200. The housing 500 may protect the first semiconductor chip 200. The housing 500 may be connected to the first semiconductor chip 200.

The housing 500 may include first to fourth lenses 510 to 740. The first to fourth lenses 510 to 540 may be connected to the housing 500. The first to fourth lenses 510 to 540 may transfer light to the first semiconductor chip 200.

In one embodiment, four lenses are shown in the image sensor package. In another embodiment, the second to fourth lenses 520 to 540 include curved surfaces. In yet another embodiment, the second to fourth lenses 520 to 540 may include flat surfaces.

In one embodiment, an underfill layer may be included between the first semiconductor chips 200. The underfill layer may wrap the solder bump 105.

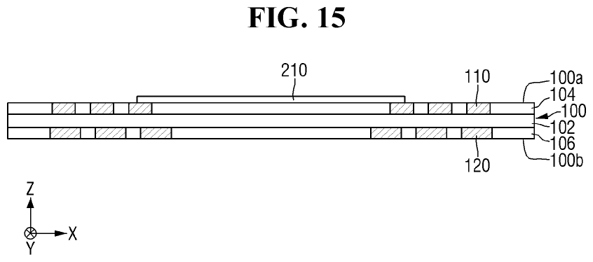

FIGS. 15 to 22 are intermediate stage diagrams for illustrating a method of fabricating the semiconductor package according to some embodiments.

Referring to FIG. 15, an attachment film 210 is formed on the first package substrate 100.

The first package substrate 100 may be a substrate for a semiconductor package. As an example, the first package substrate 100 may be a printed circuit board (PCB). The first package substrate 100 may include a first side 100a and a second side 100b that are opposite to each other. In some embodiments, the first package substrate 100 may include a first wiring layer 102, a first substrate pad 110, and a second substrate pad 120.

The attachment film 210 may be formed on the first side 100a of the first package substrate 100. The attachment film 210 may include, for example, but not limited to, liquid epoxy, adhesive tape or conductive media.

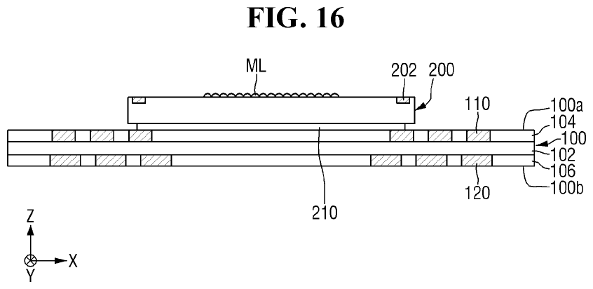

Referring to FIG. 16, the first semiconductor chip 200 is attached onto the attachment film 210.

The first semiconductor chip 200 is attached onto the attachment film 210 and fixed onto the first side 100a of the first package substrate 100.

In some embodiments, the first semiconductor chip 200 may be an image sensor chip. For example, the first semiconductor chip 200 may include a plurality of microlenses ML.

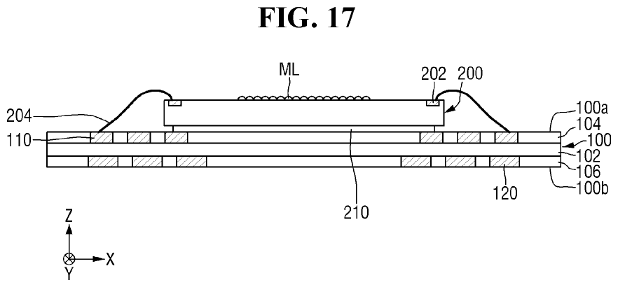

Referring to FIG. 17, a bonding wire 204 that connects the first package substrate 100 and the first semiconductor chip 200 is formed.

As an example, the first semiconductor chip 200 may include a first chip pad 202 exposed from the upper side of the first semiconductor chip 200. The bonding wire 204 may connect the first substrate pad 110 of the first package substrate 100 and the first chip pad 202 of the first semiconductor chip 200. The bonding wire 204 may include, but not limited to, metal such as gold (Au).

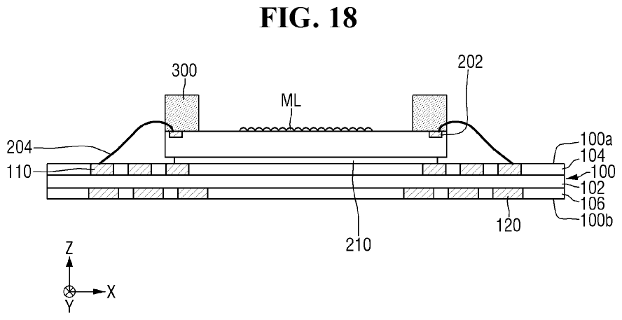

Referring to FIG. 18, the adhesive layer 300 is formed on the first semiconductor chip 200.

In some embodiments, the adhesive layer 300 may extend along the edge of the first semiconductor chip 200 to form a closed ring from the planar viewpoint. That is, the adhesive layer 300 may form a dam structure on the upper side of the first semiconductor chip 200. In some embodiments, the adhesive layer 300 may surround a plurality of microlenses ML from the planar viewpoint.

The adhesive layer 300 may include, for example, but not limited to, an epoxy resin composition containing a filler.

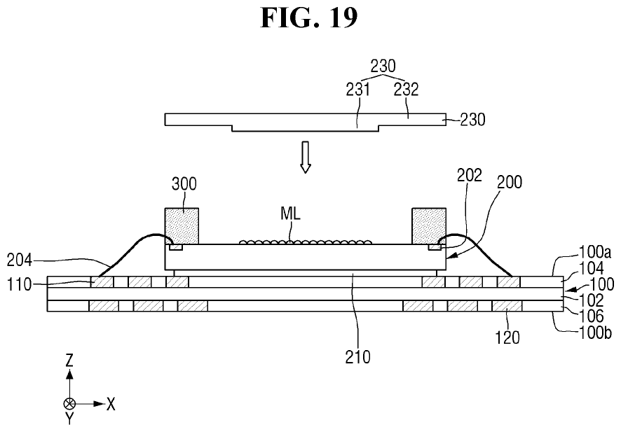

Referring to FIG. 19, a transparent substrate 230 is attached onto the adhesive layer 300.

The transparent substrate 230 may be, for example, but not limited to, a glass substrate or a plastic substrate. The transparent substrate 230 may be opposite to the first semiconductor chip 200.

The transparent substrate 230 may include a first region 231 and a second region 232. The first region 231 may protrude downward from the second region 232. The first region 231 of the transparent substrate 230 may protrude toward the microlens ML of the first semiconductor chip 200. The transparent substrate 230 may be attached onto the adhesive layer 300 such that the second region 232 of the transparent substrate 230 overlaps the adhesive layer 300.

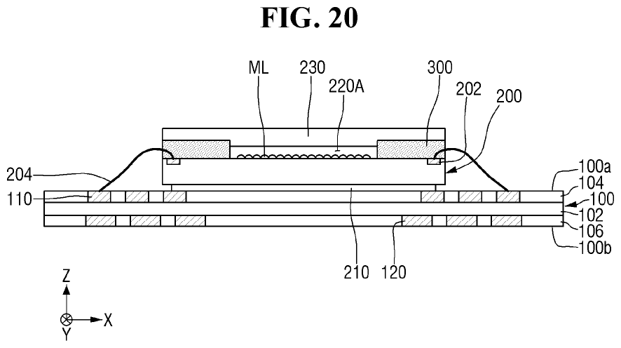

Referring to FIG. 20, the adhesive layer 300 is cured.

For example, the adhesive layer 300 may be cured by emitting ultraviolet (UL) light. While the adhesive layer 300 is cured, the transparent substrate 230 and the first semiconductor chip 200 may be attached. The form of the adhesive layer 300 may be deformed to surround the side walls of the first region 231 of the transparent substrate 230.

Accordingly, a gap 220A may be defined between the first semiconductor chip 200 and the transparent substrate 230. In some embodiments, the transparent substrate 230 may be opposite to the microlenses ML of the first semiconductor chip 200. That is, the plurality of microlenses ML of the first semiconductor chip 200 may be disposed inside the gap 220A.

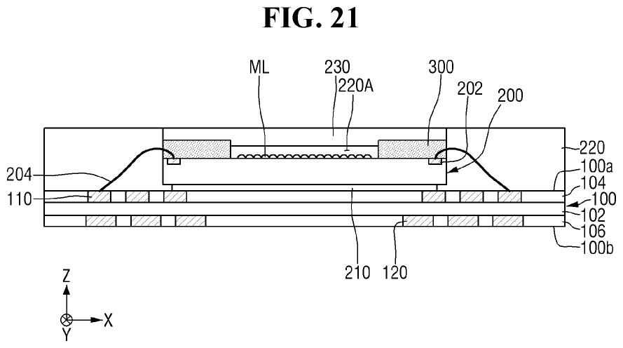

Referring to FIG. 21, a molding film 220 is formed on the first side 100a of the first package substrate 100.

The molding film 220 may be spaced apart from the first semiconductor chip 200 to surround the side surfaces of the first semiconductor chip 200. The molding film 220 may surround the side walls of the first semiconductor chip 200, the transparent substrate 230 and the adhesive layer 300. The molding film 220 may extend along the edge of the first package substrate 100 to form a closed ring from the planar viewpoint. The molding film 220 may form a dam structure on the first package substrate 100. For example, the molding film 220 may include an epoxy resin composition.

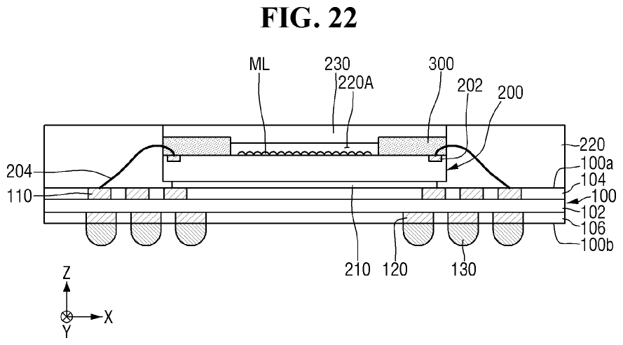

Referring to FIG. 22, the first connection terminal 130 is formed on the second side 100b of the first package substrate 100.

The first connection terminal 130 may be electrically connected to the first package substrate 100. For example, the first connection terminal 130 may be attached to the second substrate pad 120 of the first package substrate 100. The first connection terminal 130 may be, for example, solder balls, bumps, or the like. The first connection terminal 130 may include, but not limited to, metal such as tin (Sn).

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor package comprising:
a package substrate;
a semiconductor chip disposed on the package substrate;
a transparent substrate disposed on the semiconductor chip; and
an adhesive layer that is disposed between the semiconductor chip and the transparent substrate, the adhesive layer being configured to block light,
wherein the transparent substrate comprises:
a first lower side that faces the semiconductor chip,
a second lower side that faces the semiconductor chip and is disposed above the first lower side, and
a first inner side wall that connects the first lower side and the second lower side, and
wherein the adhesive layer is in contact with the second lower side and the first inner side wall.

2. The semiconductor package of claim 1, wherein the semiconductor chip is an image sensor chip that comprises a plurality of microlenses disposed below the first lower side of the transparent substrate.

3. The semiconductor package of claim 2, wherein:
the first inner side wall does not overlap the plurality of microlenses, and
a distance between an outermost microlens among the plurality of microlenses and the first inner side wall is 50 μm or less.

4. The semiconductor package of claim 2, wherein the adhesive layer does not overlap the plurality of microlenses.

5. The semiconductor package of claim 1, wherein the adhesive layer is configured to have a lower light reflectivity and a higher light absorptivity than the transparent substrate.

6. The semiconductor package of claim 1, wherein the second lower side surrounds the first lower side from a plan viewpoint.

7. The semiconductor package of claim 1, wherein a side wall of the adhesive layer that in contact with the first inner side wall is flat.

8. The semiconductor package of claim 1, wherein the adhesive layer comprises:
a first portion, and
a second portion disposed below the first portion and the second portion having a smaller width than the first portion, and
wherein the first portion is in contact with the second lower side and the first inner side wall.

9. The semiconductor package of claim 8, wherein the first portion protrudes toward the first inner side wall beyond the second portion.

10. The semiconductor package of claim 1, wherein an upper side of the transparent substrate is flat.

11. The semiconductor package of claim 1, wherein the transparent substrate further comprises:
a third lower side disposed above the second lower side, and
a second inner side wall that connects the second lower side and the third lower side, and
wherein the adhesive layer is in contact with the second lower side, the first inner side wall, the third lower side and the second inner side wall.

12. The semiconductor package of claim 1, wherein the adhesive layer is in contact with an upper side of the semiconductor chip.

13. An image sensor package comprising:
a package substrate;
an image sensor chip disposed on the package substrate, the image sensor chip comprising a plurality of microlenses;
a transparent substrate disposed on the image sensor chip; and
an adhesive layer disposed between the image sensor chip and the transparent substrate, the adhesive layer configured to block light,
wherein the transparent substrate comprises a protrusion protruding toward the image sensor chip in a central region of the transparent substrate that overlaps the plurality of microlenses, and
wherein the adhesive layer is in contact with an upper side of the image sensor chip, and the adhesive layer is in contact with a side surface of the protrusion to surround the protrusion.

14. The image sensor package of claim 13, wherein an outer side wall of the adhesive layer is recessed concavely toward the protrusion.

15. The image sensor package of claim 13, wherein a width of the protrusion is greater than or equal to a width of a region in which the plurality of microlenses are disposed.

16. The image sensor package of claim 13, further comprising a molding film that surrounds the image sensor chip, the transparent substrate, and the adhesive layer on the package substrate.

17. The image sensor package of claim 13, wherein the adhesive layer does not overlap a lower side of the protrusion.

18. The image sensor package of claim 13, wherein the adhesive layer is opaque, and the adhesive layer is configured to have a lower light reflectivity and a higher light absorptivity than the transparent substrate.

19. An image sensor package comprising:
a package substrate;
an image sensor chip disposed on the package substrate, the image sensor comprising a plurality of microlenses;
a transparent substrate disposed on the image sensor chip, the transparent substrate comprising:
a first portion having a first width, and
a second portion disposed on the first portion and the second portion having a second width greater than the first width; and
an adhesive layer which extends along an edge of the image sensor chip below the transparent substrate, the adhesive layer being configured to block light,
wherein the adhesive layer is in contact with an upper side of the image sensor chip, a side wall of the first portion, and a lower side of the second portion.

20. The image sensor package of claim 19, wherein the first portion overlaps the plurality of microlenses, and
wherein the side wall of the first portion is spaced apart from the plurality of microlenses by a distance of 50 μm or less.
